(19) United States
(12) Patent Application Publication
(10) Pub. No.: US 2025/0046710 A1
(43) Pub. Date: Feb. 6, 2025

(54) DEVICE PACKAGES INCLUDING COMMAND/ADDRESS CONNECTIONS, AND RELATED ELECTRONIC SYSTEMS

(71) Applicant: Micron Technology Inc., Boise, ID (US)

(72) Inventors: Scott Smith, Plano, TX (US); Travis M. Jensen, Boise, ID (US)

(21) Appl. No.: 18/755,055

(22) Filed: Jun. 26, 2024

Related U.S. Application Data
(60) Provisional application No. 63/516,833, filed on Jul. 31, 2023.

(51) Int. Cl. H01L 23/528; H01L 23/00; H01L 23/498; H01L 23/538; H01L 25/065; H10B 80/00

(52) U.S. Cl. CPC H01L 23/5283; H01L 23/5286; H01L 23/5386; H01L 24/05; H01L 25/0657; H01L 23/49811; H01L 23/49838; H01L 2224/05569; H01L 2225/06555; H01L 2924/1436; H10B 80/00

(57) ABSTRACT

An assembly includes a first die, and a second die arranged face-to-face with the first die. The first die includes a first pad, a second pad at a vertical elevation of the first pad, and mirror function circuitry configured to swap functionalities of the first pad and the second pad. The second die includes an additional first pad corresponding to the first pad of the first die, and an additional second pad at a vertical elevation of the additional first pad and corresponding to the second pad of the first die. The additional first pad is coupled to the second pad of the first die. The additional second pad is coupled to the first pad of the first die. Additional assemblies and electronic systems are also described.

### CROSS-REFERENCE TO RELATED APPLICATION

This application claims the benefit under 35 U.S.C. § 119(e) of U.S. Provisional Patent Application Ser. No. 63/516,833, filed Jul. 31, 2023, the disclosure of which is hereby incorporated herein in its entirety by this reference.

### TECHNICAL FIELD

This disclosure relates generally to electronic systems including dual die assemblies utilized on an electronic system.

### BACKGROUND

Multiple semiconductor dies are frequently integrated into a single package using Die-to-Die (D2D) packaging techniques. One such packaging technique includes D2D packaging with a passive interposer, also referred to as “DDP” packaging. In some examples, a pair of semiconductor dies are packaged together in a face-to-face (F2F) arrangement relative to one another. A F2F arrangement can permit a single conductive RDL structure to be utilized for accessing each of the semiconductor dies, which can enhance access speeds as compared to configurations in which the semiconductor dies are provided in a back-to-face (B2F) arrangement relative to one another. Conventional conductive RDL structures for F2F arrangements can require complex patterns to facilitate desired electrical connection of pads of neighboring semiconductor dies. In some examples, due to packaging constraints and tight pad pitch, it is difficult or impractical to desirably electrically connect pads of neighboring semiconductor dies using conventional conductive RDL structure configurations.

### BRIEF DESCRIPTION OF THE DRAWINGS

FIG. 1 is a simplified, longitudinal cross-sectional side view of an assembly including a pair of dies arranged F2F relative to one another.

FIG. 2 is a simplified, longitudinal cross-sectional view of an assembly including a pair of dies arranged F2F relative to one another, in accordance with embodiments of the disclosure.

FIG. 3 is a simplified schematic view of a die of the assembly shown in FIG. 2, in accordance with embodiments of the disclosure.

FIG. 4 is a simplified schematic view of a configuration for the assembly shown in FIG. 2, in accordance with embodiments of the disclosure.

FIG. 5 is a schematic view of an additional configuration for the assembly shown in FIG. 2, in accordance with additional embodiments of the disclosure.

FIG. 6 is a simplified block diagram of an electronic system, in accordance with embodiments of the disclosure.

### DETAILED DESCRIPTION

The illustrations presented herein are not actual views of any dual die assembly, electronic systems, or any component thereof, but are merely idealized representations, which are employed to describe embodiments of the present invention.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be least 90.0 percent met, at least 95.0 percent met, at least 99.0 percent met, at least 99.9 percent met, or even 100.0 percent met.

As used herein, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the phrase “coupled to” refers to structures operatively connected with each other, such as electrically connected through a direct Ohmic connection or through an indirect connection (e.g., by way of another structure).

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

In some examples, apparatuses are configured to have a pair of dies oriented in a F2F arrangement relative with one another while still enabling desired coupling of predetermined pads of the dies with one another. The F2F arrangement may permit relatively fewer and/or less tortuous conductive RDL structure to be utilized for accessing predetermined circuitries of the dies, which may improve access speeds as compared to conventional configurations.

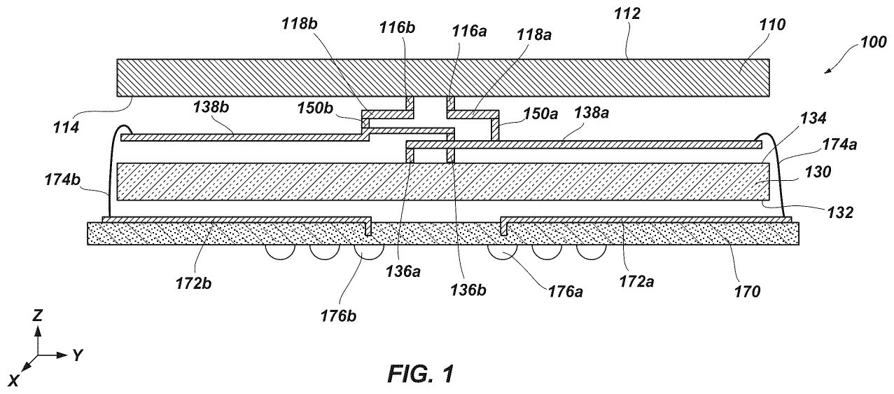

FIG. 1 is a simplified, longitudinal cross-sectional view of an assembly 100 (also referred to herein as a dual die assembly 100) including a first 110 and a second die 130 (also referred to herein as a “pair of dies”) arranged F2F relative to one another. The first die 110 may include a back surface 112 and a facing surface 114. The facing surface 114 may be positioned relatively more proximate to the second die 130 than the back surface 112. The back surface 112 may be vertically positioned opposite the facing surface 114. The first die 110 may further comprise a first pad 116a and a second pad 116b on the facing surface 114. The first pad 116a and the second pad 116b may be coupled to first conductive redistribution layer (RDL) structures 118a (e.g., first conductive routing) and second conductive RDL structures 118b (e.g., second conductive routing), respectively.

The second die 130 may include a back surface 132 and a facing surface 134. The facing surface 134 may be relatively more proximate the first die 110 than the back surface 132. The back surface 132 may be vertically positioned opposite the facing surface 134. The second die 130 may further comprise a first pad 136a and a second pad 136b on the facing surface 134. The first pad 136a and the second pad 136b may be coupled to a first additional conductive RDL structures 138a (e.g., first additional conductive routing) and second additional conductive RDL structures 138b (e.g., second additional conductive routing) conductive RDL structure 138b, respectively.

The first and second conductive RDL structure 118a, 118b of the first die 110 are coupled to the first and second additional conductive RDL structure 138a, 138b, respectively, of the second die 130. The coupling may be facilitated by at least one first conductive interconnect 150a coupling the first conductive RDL structure 118a of the first die 110 to the first additional conductive RDL structure 138a of the second die 130, and by at least one second conductive interconnect 150b coupling the second conductive RDL structure 118b of the first die 110 to the second additional conductive RDL structure 138b of the second die 130. The first and second conductive interconnects 150a, 150b may comprise solder bumps, conductively filled vias, and/or another conductive structure.

When the first die 110 and the second die 130 are in a F2F arrangement as shown in FIG. 1, corresponding pads (e.g., the first pad 116a of the first die 110 and the first pad 136a of the second die 130; the second pad 116b of the first die 110 and the second pad 136b of the second die 130) of the first die 110 and the second die 130 may not horizontally align (e.g., in the X-direction, in the Y-direction) with one another. For example, due to the horizontal positioning of additional features (e.g., structures, materials, devices) of the first die 110 and the second die 130, the first pad 116a of the first die 110 may not horizontally overlap the first pad 136a of the second die 130; and the second pad 116b of the first die 110 may not horizontally overlap with the second pad 136b of the second die 130. Instead, because the first and second dies 110, 130 are arranged F2F with one another, first pad 116a of the first die 110 may be completely horizontally offset (e.g., in the X-direction, in the Y-direction) from the first pad 136a of the second die 130; and the second pad 116b of the first die 110 may be completely horizontally offset (e.g., in the X-direction, in the Y-direction) from the second pad 136b of the second die 130. For simplicity and ease of understanding the drawings and related described, the first pad 116a of the first die 110 and the first pad 136a of the second die 130 are collectively referred to herein as “corresponding first pads 116a, 136a”; and the second pad 116b of the first die 110 and the second pad 136b of the second die 130 are collectively referred to herein as “corresponding second pads 116b, 136b.”

The first and second conductive RDL structures 118a, 118b and the first and second additional conductive RDL structures 138a, 138b are configured to resolve the horizontal misalignment of the corresponding first pads 116a, 136a and the horizontal misalignment of the corresponding second pads 116b, 136b. For example, as shown in FIG. 1, the first and second additional conductive RDL structures 138a, 138b may be configured to horizontally cross over (e.g., partially horizontally overlap) one another to facilitate coupling of the corresponding first pads 116a, 136a and coupling of the corresponding second pads 116b, 136b. The first additional conductive RDL structure 138a of the second die 130 connected to the first pad 136a may horizontally extend from the first pad 136a and may continue past the second pad 136b of the second die 130, so as to permit coupling of first additional conductive RDL structure 138a with the first conductive interconnect 150a coupled to the first conductive RDL structure 118a. The second pad 136b of the second die 130 may be horizontally interposed between the first pad 136a of the second die 130 and the first conductive interconnect 150a. Similarly, the second additional conductive RDL structure 138b of the second die 130 connected to the second pad 136b may horizontally extend from the second pad 136b and may continue past the first pad 136a of the second die 130, so as to permit coupling of second additional conductive RDL structure 138b with the second conductive interconnect 150b coupled to the second conductive RDL structure 118b. The first pad 136a of the second die 130 may be horizontally interposed between the second pad 136b of the second die 130 and the second conductive interconnect 150b. To facilitate horizontal cross-over of the first and second additional conductive RDL structures 138a, 138b at least a portion of the first additional conductive RDL structure 138a is vertically offset from at least a portion of the second additional conductive RDL structure 138b. For example, as shown in FIG. 1, at least a portion (e.g., at least a horizontally overlapping portion) of the second additional conductive RDL structure 138b may vertically overlie (or may vertically underlie) at least a portion of the first additional conductive RDL structure 138a. However, such horizontal cross over configurations can result in enhanced device complexity and fabrication costs, especially for configurations of the first die 110 and the second die 130 having greater feature densities, smaller horizontal area, and/or various feature horizontal layouts.

With corresponding first pads 116a, 136a coupled to one another via the first conductive RDL structures 118a, 138a, both of the first pads 116a, 136a of the first and second dies 110, 130 may be electrically connected to a substrate 170 by way of a first wire 174a. Similarly, with corresponding second pads 116b, 136b coupled to one another via the second conductive RDL structures 118b, 138b, both of the second pads 116b, 136b of the first and second dies 110, 130 may be electrically connected to the substrate 170 by way of a second wire 174b. The first and second wires 174a, 174b may be coupled to first circuitries 172a and second circuitries 172b of the substrate 170, respectively. The first circuitries 172a and second circuitries 172b may be located in, on, or over the substrate 170. The substrate 170 may also include interconnect structures 176a, 176b, such as solder balls or any other structure suitable for coupling the substrate 170, and thus the dual die assembly 100, to external circuitry.

In some die configurations, packaging of dies may create constraints that make it difficult to route conductive RDL structures such that the conductive RDL structures cross over one another, as described above. In some configurations, tight pad pitch may make such cross-over configurations challenging or impractical. However, it may still be advantageous to arrange dies in a face-to-face configuration even when such configurations of the conductive RDL structures are impractical.

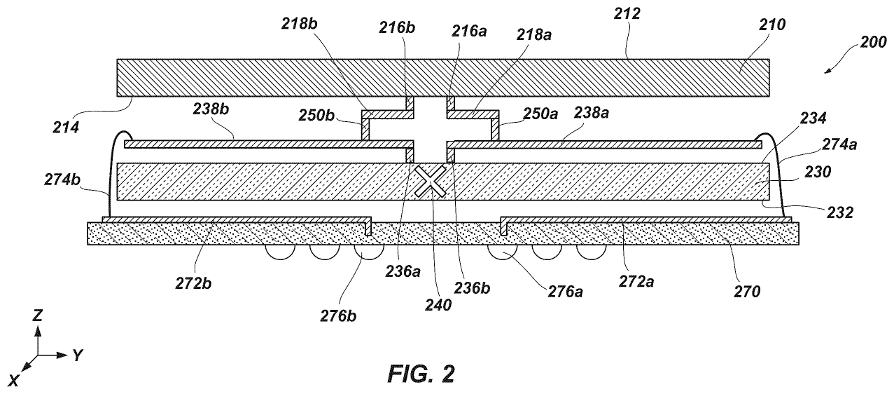

FIG. 2 is a simplified, longitudinal cross-sectional view of an assembly 200 (also referred to herein as a dual die assembly 200) including a first die 210 and a second dies 230 (also referred to herein as a “pair of dies”) arranged F2F relative to one another, in accordance with embodiments of the disclosure. The dual die assembly 200 may be utilized in a double data rate synchronous dynamic random-access memory (DDR SDRAM). The first die 210 may include a back surface 212 and a facing surface 214. The facing surface 214 may be positioned relatively more proximate to the second die 230 than the back surface 212. The back surface 212 may be vertically positioned opposite the facing surface 214. The first die 210 may further include a first pad 216a and a second pad 216b on the facing surface 214. The first pad 216a and the second pad 216b are horizontally offset from one another in the Y-direction. The first pad 216a and the second pad 216b may be coupled to first conductive RDL structures 118a (e.g., first conductive routing) and second conductive RDL structures 218b (e.g., second conductive routing), respectively.

The second die 230 may include a back surface 232 and a facing surface 234 (also referred to herein as a “face surface”). The facing surface 234 may be relatively more proximate the first die 210 than the than the back surface 232. The back surface 232 may be vertically positioned opposite the facing surface 234. The second die 230 may further include a first pad 236a and a second pad 236b on the facing surface 234. The first pad 236a and the second pad 236b are horizontally offset from one another in the Y-direction. The first pad 236a and the second pad 236b may be coupled to a first additional conductive RDL structure 238a (e.g., first additional conductive routing) and second additional conductive RDL structure 238b (e.g., second additional conductive routing), respectively.

Similar to the dual die assembly 100 previously described with reference to FIG. 1, in the dual die assembly 200, the F2F arrangement of the first die 210 and the second die 230 may result in horizontal misalignment (e.g., in the X-direction, in the Y-direction) of at least some corresponding pads (e.g., the first pad 216a of the first die 210 and the first pad 236a of the second die 230; the second pad 216b of the first die 210 and the second pad 236b of the second die 230) of the first die 210 and the second die 230. For example, due to the horizontal positioning of additional features (e.g., structures, materials, devices) of the first die 210 and the second die 230, the first pad 216a of the first die 210 may not horizontally overlap the first pad 236a of the second die 230 and the second pad 216b of the first die 210 may not horizontally overlap with the second pad 236b of the second die 230. Instead, because the first and second dies 210, 230 are arranged F2F with one another, first pad 216a of the first die 210 may be completely horizontally offset (e.g., in the X-direction, in the Y-direction) from the first pad 236a of the second die 230; and the second pad 216b of the first die 210 may be completely horizontally offset (e.g., in the X-direction, in the Y-direction) from the second pad 236b of the second die 230. For simplicity and ease of understanding the drawings and related described, the first pad 216a of the first die 210 and the first pad 236a of the second die 230 are collectively referred to herein as “corresponding first pads 216a, 236a”; and the second pad 216b of the first die 210 and the second pad 236b of the second die 230 are collectively referred to herein as “corresponding second pads 216b, 236b.”

In shown in FIG. 2, in contrast to the cross-over arrangement (e.g., of the first and second conductive RDL structures 118a, 118b and the first and second additional conductive RDL structures 138a, 138b) previously described with reference to FIG. 1, the dual die assembly 200 is configured for a mirror function circuitry 240 in the second die 230 that permits the first pad 236a and the second pad 236b of the second die 230 to swap assignments. When the mirror function circuitry 240 of the second die 230 is enabled (e.g., active), the first pad 236a may have (e.g., be assigned) the role of the second pad 236b, and the second pad 236b may be assigned the role of the first pad 236a.

In dual die assembly 200, at least the second die 230 may include mirror function circuitry 240 based on the specifications of the first and second dies 210, 230. For example, for first and second dies 210, 230 configured according to a DDR5 specification, the second die 230 may include a mirror function circuitry 240 that may be operable to swap functionality of pairs of pads of the second die 230. For example, if the second die 230 includes pairs of pads identified as (CA0, CA1), (CA2, CA3), (CA4, CA5), . . . (CAn-1, CAn), then the mirror function circuitry 240 may be operable to effectively swap the assignments of these pairs of pads to effectively operate as (CA1, CA0), (CA3, CA2), (CA5, CA4), . . . (CAn, CAn-1). The mirror function circuitry 240 may be configured to selectively swap circuitry that one pad of an individual pair of pads is electrically connected to (e.g., by way of the mirror function circuitry 240) with additional circuitry that the other pad of the individual pair of pads is electrically connected to (e.g., also by way of the mirror function circuitry 240), and vice versa. Such a mirror function circuitry 240 may be beneficial in a variety of circumstances, such as for two-sided module clamshell component placements.

In FIG. 2, as the functionalities (e.g., electrical connections to additional, different circuitries) of the first and second pads 236a, 236b of the second die 230 may be swapped by way of the mirror function circuitry 240, the first pad 216a of the first die 210 may be selectively coupled to the second pad 236b of the second die 230. The second pad 236b of the second die 230 may be imparted with the functionality of the first pad 236a of the second die 230 by way of the mirror function circuitry 240. The first pad 216a of the first die 210 may be coupled to the second pad 236b of the second die 230 by way of the first conductive RDL structure 218a of the first die 210, the second additional conductive RDL structure 238b of the second die 230, and a first interconnect 250a. For example, the first pad 216a may be coupled to the first conductive RDL structure 218a, the second pad 236b may be coupled to the second additional conductive RDL structure 238b, and the first conductive RDL structure 218a may be coupled to the second additional conductive RDL structure 238b via the first interconnect 250a.

In addition, the second pad 216b of the first die 210 may be coupled to the first pad 236a of the second die 230. The first pad 236a of the second die 230 may be imparted with the functionality of the second pad 236b of the second die 230 by way of the mirror function circuitry 240. The second pad 216b of the first die 210 may be coupled to the first pad 236a of the second die 230 by way of the second conductive RDL structure 218b of the first die 210, the first additional conductive RDL structures 238a of the second die 230, and a second interconnect 250b. For example, the second pad 216b may be coupled to the second conductive RDL structure 218b, the first pad 236a may be coupled to the first additional conductive RDL structures 238a, and the second conductive RDL structure 218b may be coupled to the firs first additional conductive RDL structures 238a by way of the second interconnect 250b.

As shown in FIG. 2, due to the mirror function circuitry 240 of the second die 230, the dual die assembly 200 may have F2F arrangement of the first and second dies 210, 230 without having the first and second conductive RDL structures 218a, 218b horizontally cross-over one another and without have the first and second additional conductive RDL structures 238a, 238b horizontally cross-over one another. For example, as shown in FIG. 2, the first and second additional conductive RDL structures 238a, 238b may be completely horizontally offset from one another (e.g., do not partially horizontally overlap) one another in the Y-direction to but may still facilitate coupling of the corresponding first pads 216a, 236a and coupling of the corresponding second pads 216b, 236b. The first additional conductive RDL structure 238a of the second die 230 connected to the first pad 236a may horizontally extend from the first pad 236a and may continue away from the second pad 236b of the second die 230. The first additional conductive RDL structure 238a may be completely horizontally offset from the second pad 236b in the Y-direction, and may horizontally extend toward and couple with the second conductive interconnect 250b coupled to the second conductive RDL structure 218b of the first die 210. The first pad 236a of the second die 230 may be horizontally interposed between the second pad 236b of the second die 230 and the second conductive interconnect 250b. Similarly, the second additional conductive RDL structure 238b of the second die 230 connected to the second pad 236b may horizontally extend from the second pad 236b and may continue away from the first pad 236a of the second die 230. The second additional conductive RDL structure 238b may be completely horizontally offset from the first pad 236a in the Y-direction, and may horizontally extend toward and couple with the first conductive interconnect 250a coupled to the first conductive RDL structure 218a of the first die 210. The second pad 236b of the second die 230 may be horizontally interposed between the first pad 236a of the second die 230 and the first conductive interconnect 250a. As a result of the mirror function circuitry 240 of the second die 230, entireties of the first and second additional conductive RDL structures 238a, 238b may be substantially vertically aligned (e.g., in the Z-direction) with one another. For example, as shown in FIG. 2, no portions of the second additional conductive RDL structure 238b may be vertically offset from any portions of the first additional conductive RDL structure 238a. Accordingly, the mirror function circuitry 240 of the dual die assembly 200 may reduce device complexity and fabrication costs, especially for configurations of the first die 210 and the second die 230 having greater feature densities, smaller horizontal area, and/or various feature horizontal layouts.

With the first pad 216a of the first die 210 and the second pad 236b (effectively serving as the first pad 236a through use and operation of the mirror function circuitry 240) coupled to one another via the first conductive RDL structure 218a and the second additional conductive RDL structure 238b, the first pad 216a and the second pad 236b may be electrically connected to a substrate 270 by way of a first wire 274a. Similarly, with the second pad 216b of the first die 210 and the first pad 236a (effectively serving as the second pad 236b through use and operation of the mirror function circuitry 240) coupled to one another via the second conductive RDL structure 218b and the first additional conductive RDL structures 238a, the second pad 216b and the first pad 236a may be electrically connected to the substrate 270 by way of a second wire 274b. The first and second wires 274a, 274b may be coupled to first circuitries 272a and second circuitries 272b of the substrate 270, respectively. The first circuitries 272a and second circuitries 272b may be located in, on, or over the substrate 270. The substrate 270 may also include interconnect structures 276a, 276b, such as solder balls or any other structure suitable for coupling the substrate 270, and thus the dual die assembly 200, to external circuitry.

Thus, in accordance with embodiments of the disclosure, an assembly includes a first die, and a second die arranged face-to-face with the first die. The first die includes a first pad on a facing surface of the first die, a second pad on the facing surface of the first die, and mirror function circuitry configured to swap functionalities of the first pad and the second pad. The second die includes an additional first pad on an additional facing surface of the second die, the additional first pad corresponding to the first pad of the first die, and an additional second pad on the additional facing surface of the second die, the additional second pad corresponding to the second pad of the first die. The additional first pad is coupled to the second pad of the first die. The additional second pad is coupled to the first pad of the first die.

Since mirror function circuitry for a die is part of a specification of the die, dual die assemblies (e.g., the dual die assembly 200) of the disclosure may be operable to utilize the mirror function circuitry (e.g., the mirror function circuitry 240) of a die (e.g., the second die 230) thereof to facilitate a F2F arrangement of dies (e.g., the first die 210 and the second die 230) of the dual die assembly while also maintaining normal use and operation of the mirror function circuitry. In other words, the dies of the dual die assembly can utilize the mirror function circuitry of one of the dies to facilitate coupling of pads of the dies without complex conductive RDL structure configurations (e.g., horizontal cross-over configurates) with either of the dies, while also maintaining normal use of operation of the mirror function circuitry for the dies.

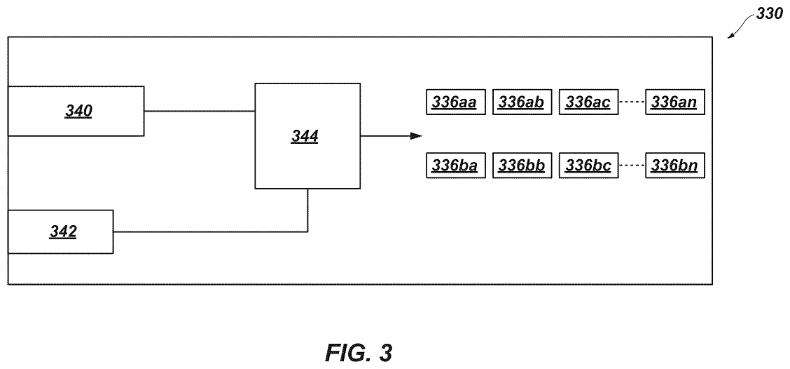

FIG. 3 is a simplified schematic view of a die 330 (e.g., a semiconductor die), in accordance with embodiments of the disclosure. The die 330 may be employed in the dual die assembly 200 previously described with reference to FIG. 2. In some embodiments, the die 330 is used as the second die 230 of the dual die assembly 200 previously described above with reference to FIG. 2. In additional embodiments, the die 330 is used as the first die 210 of the dual die assembly 200 previously described above with reference to FIG. 2. The die 330 may include a plurality of pads 336, such as first pads 336aa, 336ab, 336ac . . . 336an; and second pads 336ba, 336bb, 336bc . . . 336bn. The die 330 may further include mirror function circuitry 340. The mirror function circuitry 340 may be configured and operated to swap functionality of one or more pairs of pads of the die 330. For example, the mirror function circuitry 340 may be configured and operable to swap the functionality of one or more of the first pad 336aa and the second pad 336ba, the first pad 336ab and the second pad 336bb, the first pad 336ac and the second pad 336bc, and the first pad 336an and the second pad 336bn.

When the die 330 is incorporated into a dual die assembly (e.g., the dual die assembly 200 (FIG. 2)) having a F2F arrangement of dies, the mirror function circuitry 340 of the die 330 may be utilized to swap functionality of pads of the die 330 such that desired pads of another die (e.g., the first die 210) in F2F arrangement with the die 330 may be coupled therewith without the need for horizontal cross-over of conductive RDL structures of the die 330, as explained above with reference to FIG. 2. However, when the mirror function circuitry 340 is enabled (e.g., activated) in a dual die assembly for another purpose, the mirror function circuitry 340 may retain its other purpose and functionality. In other words, the mirror functionality of the die 330 may be inverted from a default configuration. The die 330 may, for example, include a mirror function inverter 344 operatively associated with the mirror function circuitry 340. The mirror function inverter 344 may include additional circuitry that inverts a signal output of the mirror function circuitry 340. For example, if a default state of the mirror function circuitry 340 is “off” (e.g., the mirror function circuitry is not currently active to swap functionality of first pads 336aa . . . 336an and second pads 336ba . . . 336bn), the mirror function inverter 344 may be configurated and operable to invert a signal such that the mirror function circuitry 340 is “on” (e.g., the mirror function circuitry is active to swap functionality of first pads 336aa . . . 336an and second pads 336ba . . . 336bn). Similarly, if the default state of the mirror function circuitry 340 is “on,” the mirror function inverter 344 may be configured and operable to invert a signal such that the mirror function is “off.”

When two (2) dies of a dual die assembly (e.g., the dual die assembly 200 (FIG. 2)) have mirror function circuitry 340, only one of the dies (e.g., only one die 330) may have the functionality of its pads swapped or inverted via the mirror function circuitry 340. Accordingly, the die 330 may further include an inverter trigger 342. The inverter trigger 342 may include further circuitry configured and operable to control the mirror function inverter 344 as desired. In a dual die assembly (e.g., the dual die assembly 200 (FIG. 2)) including two (2) dies 330, the inverter trigger 342 may be operable to activate the mirror function inverter 344 in one of the two (2) dies 330, as will be described in more detail below. In this manner, the one of the two (2) dies 330 may utilize the mirror function circuitry 340 thereof to facilitate the F2F arrangement of the two (2) dies 330, while also maintaining other desired uses and functions of the mirror function circuitries 340 of the dual die assembly.

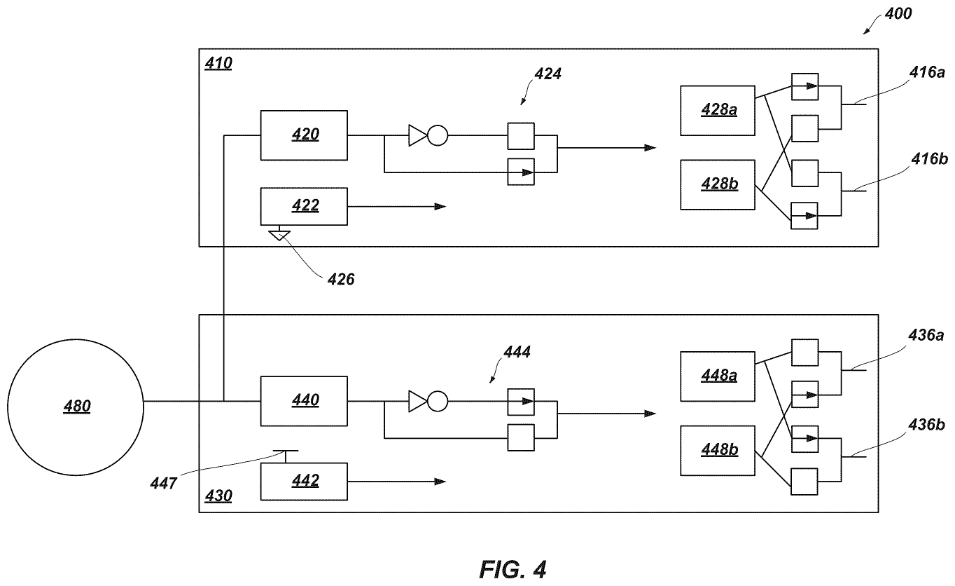

FIG. 4 is a simplified schematic view of an assembly 400 (also referred to herein as a “dual die assembly 400”), in accordance with embodiments of the disclosure. The dual die assembly 400 may be employed as the dual die assembly 200 previously described with reference to FIG. 2. The dual die assembly 400 may include a first die 410 (e.g., corresponding to the first die 210 (FIG. 2)) and a second die 430 (e.g., corresponding to the second die 230 (FIG. 2)). The first die 410 and the second die 430 may individually include pads substantially similar to those previously described herein for the first die 210 (FIG. 2) and the second die 230 (FIG. 2), respectively. For example, the first die 410 may include a first pad 416a (e.g., corresponding to the first pad 216a (FIG. 2)) and a second pad 416b (e.g., corresponding to the second pad 216b (FIG. 2)). In addition, the second die 430 may include a first pad 436a (e.g., corresponding to the first pad 236a (FIG. 2)) and a second pad 436b (e.g., corresponding to the second pad 236b (FIG. 2)). The first and second dies 410, 430 may be oriented in a F2F arrangement relative to one another, similar to the F2F arrangement of the first and second dies 210, 230 previously described with reference to FIG. 2. The first pad 416a of the first die 410 may be coupled to the second pad 436b of the second die 430, and the second pad 416b of the first die 410 may be coupled to the first pad 436a of the second die 430.

Similar to the die 330 discussed above with reference to FIG. 3, each of the first die 410 and the second die 430 may include mirror function circuitry, a mirror function inverter, and an inverter trigger. For example, the first die 410 may include a mirror function circuitry 420 (e.g., corresponding to the mirror function circuitry 340 (FIG. 3)), a mirror function inverter 424 (e.g., corresponding to the mirror function inverter 344 (FIG. 3)), and an inverter trigger 422 (e.g., corresponding to the inverter trigger 342 (FIG. 3)). Similarly, the second die 430 may include mirror function circuitry 440 (e.g., corresponding to the mirror function circuitry 340 (FIG. 3)), a mirror function inverter 444 (e.g., corresponding to the mirror function inverter 344 (FIG. 3)), and an inverter trigger 442 (e.g., corresponding to the inverter trigger 342 (FIG. 3)). The mirror function circuitries 420, 440 of the first and second dies 410, 430 may be coupled to mirror package circuitry 480. During use and operation, signals output by the mirror package circuitry 480 may determine if the mirror function circuitry of one of the first die 410 and the second die 430 should be in an “on” state or an “off” state.

With the first and second dies 410, 430 in a F2F arrangement relative to one another, signals output by the mirror function circuitry 420, 440 of one of the first and second dies 410, 430 may be inverted to facilitate desired coupling of the pads 416a, 436b, 416b, 436a. The first die 410 may include a mirror function inverter 424 configured to receive a mirror function signal output by the mirror function circuitry 420, and to output a mirror signal to a first pad input buffer 428a and a second pad input buffer 428b. The mirror signal output by the mirror function inverter 424 may be the same as the signal received from the mirror function circuitry 420, or may be inverted relative to the signal received from the mirror function circuitry 420. Whether the mirror function inverter 424 inverts the signal received from the mirror function circuitry 420 may be based on a signal received from the inverter trigger 422. The inverter trigger 422 may be used to identify which of the first die 410 and the second die 430 is the top or bottom die in the stack of the dual die assembly 400.

Output driver supply (V_{DDQ}) potential or ground (V_{SS}) potential may be utilized to control how the inverter trigger 422 effects whether signals output from mirror function circuitry 420 are inverted by the mirror function inverter 424. For example, the inverter trigger 422 may include a bond pad positioned to receive one of a V_{DDQ} potential and a V_{SS} potential to determine whether the mirror function inverter 424 should be activated. For example, when the bond pad of the inverter trigger 422 is supplied with a V_{DDQ} potential, the inverter trigger 422 may signal the mirror function inverter 424 to invert the signal input to the mirror function inverter 424 from the mirror function circuitry 420. When the bond pad of the inverter trigger 422 supplied with a V_{SS} potential, the inverter trigger 422 may signal the mirror function inverter 424 to remain inactive and to not invert the input signal to the mirror function inverter 424 from the mirror function circuitry 420. In FIG. 4, the bond pad of the inverter trigger 422 may be electrically connected to a V_{SS} terminal 426 of the first die 410. Thus, the mirror function inverter 424 may not invert the signal input received from the mirror function circuitry 420, and the mirror function circuitry 420 in the first die 410 may be “OFF” (e.g., inactive) by default. Thus, by default, the first input buffer 428a may be configured to output to the first pad 416a, and the second input buffer 428b is configured to output to the second pad 416b (e.g., the functionality of first and second pads 416a, 416b may not be swapped by default).

Similar to the first die 410, the second die 430 may include a mirror function inverter 444 configured to receive a mirror function signal output by the mirror function circuitry 440, and to output a mirror signal to a first pad input buffer 448a and a second pad input buffer 448b. The mirror signal output by the mirror function inverter 444 may be the same as the signal received from the mirror function circuitry 440, or may be inverted relative to the signal received from the mirror function circuitry 440. Whether the mirror function inverter 444 inverts the signal input to it from the mirror function circuitry 440 may be based on a signal received from the inverter trigger 442.

V_{DDQ} potential or V_{SS} potential may be utilized to control how the inverter trigger 442 effects whether signals output from the mirror function circuitry 440 are inverted by the mirror function inverter 444. For example, the inverter trigger 442 may include a bond pad positioned to receive one of a V_{DDQ} potential and a V_{SS} potential to determine whether the mirror function inverter 444 should be activated. In FIG. 4, the bond pad of the inverter trigger 442 may be electrically connected to a V_{DDQ} terminal 447 of the second die 430. Thus, the mirror function inverter 444 may invert the signal input received from the mirror function circuitry 440, and the mirror function circuitry 440 in the second die 430 may be “ON” (e.g., active) by default. Thus, by default, the first input buffer 428a may be configured to output to the second pad 416b, and the second input buffer 428b is configured to output to the first pad 416a (e.g., the functionality of first and second pads 416a, 416b may be swapped by default).

By utilizing the inverter triggers 422, 442, the first and second dies 410, 430 may be provided in a F2F arrangement relative to one another and may employ the mirror function circuitries 420, 440 to alleviate routing complexity relative to conventional configurations, without adversely affecting desirable mirror functionality in the dual die assembly 400. In the example shown in FIG. 4, the first die 410 defaults to the mirror function circuitry 420 being in an “OFF” state, and the second die 430 defaults to the mirror function circuitry 440 being in an “ON” state. If a signal from the mirror package circuitry 480 to the mirror function circuitries 420, 440 is received by the mirror function circuitries 420, 440, the mirror function inverter 424 may not invert the mirror signal output from the mirror function circuitry 420, thereby activating the mirror function in the first die 410. In addition, the mirror function inverter 444 may continue to invert the mirror signal output from the mirror function circuitry 440, deactivating the mirror function in the second die 430. Thus, the mirror functionality of the dual die assembly 400 may be maintained.

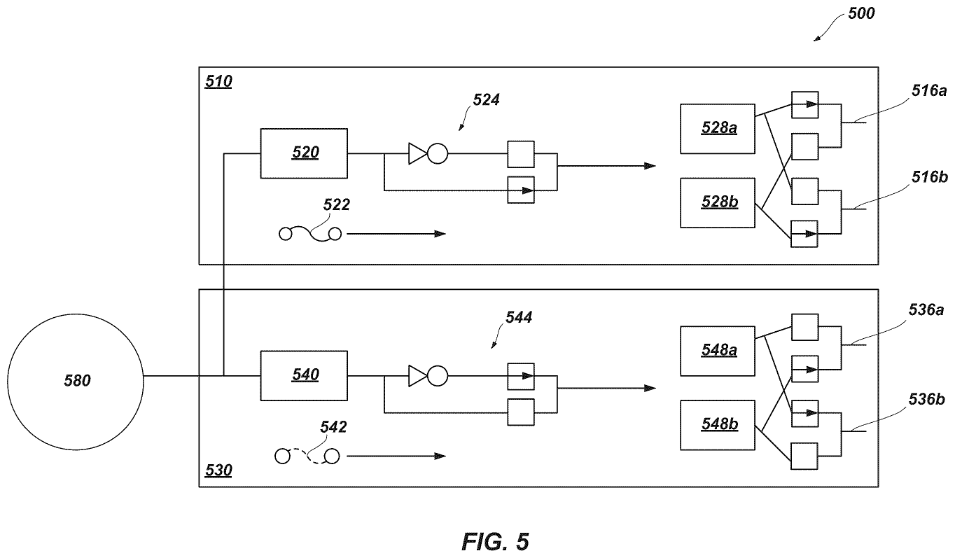

In additional embodiments, an inverter trigger of a die of an assembly of the disclosure may be configured provide a signal to a mirror function inverter of the die without the use of a bond pad. For instance, the positioning of additional features within the die may make the positioning of a bond pad for the inverter trigger within the die challenging or impractical. Accordingly, FIG. 5 shows a simplified schematic view of an assembly 500 (also referred to herein as a “dual die assembly 500”), in accordance with additional embodiments of the disclosure. The assembly 500 may include inverter triggers 522, 542 that do not include bond pads. Beyond the inverter triggers 522, 542 thereof, the dual die assembly 500 may be substantially similar to dual die assembly 400 previously described herein with reference to FIG. 4. To avoid repetition, not all features (e.g., structures, materials, regions, devices) shown in FIG. 5 are described in detail herein. Rather, unless described otherwise below, in FIG. 5, a feature designated by a reference numeral that is a 100 increment of the reference numeral of a feature previously described with reference to FIG. 4 will be understood to be substantially similar to the previously described feature. By way of non-limiting example, unless described otherwise below, features designated by the reference numerals 520, 540 in FIG. 5 respectively will be understood to be substantially similar to the mirror function circuitries 420, 440 previously described herein with reference to FIG. 4.

In FIG. 5, the inverter triggers 522, 542 of the first and second dies 510, 530 may respectively include a fuse. During fabrication of the dies 510, 530, a fuse of one of the inverter triggers 522, 542 may be shorted to permit a signal to be output to one of the mirror function inverters 524, 544. As a result, the one of the mirror function inverters 524, 544 may invert a mirror signal output from the mirror function circuitries 520, 540. In the example shown in FIG. 5, the first die 510 may include an inverter trigger 522 including a fuse that has not been shorted. Thus, the mirror function inverter 524 of the first die 510 may not be activated, and the first die 510 may default to an OFF (e.g., inactive) mirror function state. The second die 530 may include an inverter trigger 542 include a fuse that has been shorted. The shorted fuse of the inverter trigger 542 may be operable to cause the mirror function inverter 544 to invert a signal received from the mirror function circuitry 540. Thus, the second die may default to an ON (e.g., active) mirror function state. Other possible ways to trigger a mirror function inverter may also be incorporated into dies and assemblies of the disclosure, such as by way of an alternate metal mask used in wafer processing.

Thus, in accordance with embodiments of the disclosure, an assembly includes a die and an additional die vertically overlying the die. The die includes a face side, a back side vertically opposing the face side, a first bond pad on the face side, a second bond pad on the face side, and mirror function circuitry coupled to the first bond pad and the second bond pad, the mirror function circuitry configured to swap which additional circuitries the first bond pad and the second bond pad are respectively coupled to with one another. The additional die includes an additional face side relatively more proximate to the face side of the die than the back side of the die, an additional back side vertically opposing the additional face side, a first additional bond pad on the additional face side and horizontally overlapping the second bond pad of the die in a first direction, a second additional bond pad on the additional face side and horizontally overlapping the first bond pad of the die in the first direction, and additional mirror function circuitry coupled to the first additional bond pad and the second additional bond pad.

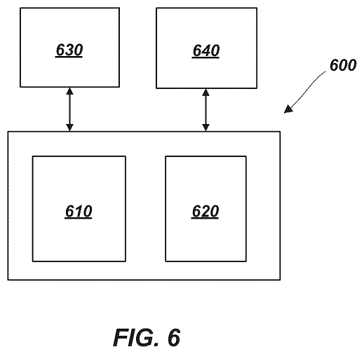

Assemblies (e.g., the dual die assemblies 200, 400, 500) may be employed in embodiments of electronic systems of the disclosure. For example, FIG. 6 is a block diagram of an electronic system 600, according to embodiments of disclosure. The electronic system 600 may comprise, for example, a computer or computer hardware component, a server or other networking hardware component, an SSD, a cellular telephone, a digital camera, a personal digital assistant (PDA), portable media (e.g., music) player, a Wi-Fi or cellular-enabled tablet such as, for example, an iPad® or SURFACE@tablet, an electronic book, or a navigation device, etc. The electronic system 600 includes at least one memory device 620. The memory device 620 may be an SSD and may include, for example, one or more of the assemblies (e.g., the dual die assemblies 200, 400, 500) of the disclosure. The electronic system 600 may further include at least one electronic signal processor device 610 (often referred to as a “microprocessor”) that is part of an integrated circuit. The electronic signal processor device 610 may include, for example, one or more of the assemblies (e.g., the dual die assemblies 200, 400, 500) of the disclosure. While the memory device 620 and the electronic signal processor device 610 are depicted as two (2) separate devices in FIG. 6, in additional embodiments, a single (e.g., only one) memory/processor device having the functionalities of the memory device 620 and the electronic signal processor device 610 is included in the electronic system 600 such as a processor device with an embedded SSD. The memory/processor device may include, for example, one or more of the assemblies (e.g., the dual die assemblies 200, 400, 500) of the disclosure. The electronic signal processor device 610 and the memory device 620 may be part of a disaggregated-die assembly on a package board substrate that may include a stiffener assembly (e.g., the dual die assemblies 200, 400, 500).

The electronic system 600 may further include one or more input devices 630 for inputting information into the electronic system 600 by a user, such as, for example, a mouse or other pointing device, a keyboard, a touchpad, a button, or a control panel. The electronic system 600 may further include one or more output devices 640 for outputting information (e.g., visual or audio output) to a user such as, for example, a monitor, a display, a printer, an audio output jack, and/or a speaker. In some embodiments, the input device 630 and the output device 640 may comprise a single touchscreen device that can be used both to input information to the electronic system 600 and to output visual information to a user. The input device 630 and the output device 640 may communicate electrically with one or more of the memory device 620 and the electronic signal processor device 610.

Thus, in accordance with embodiments of the disclosure, an electronic system includes a dual die assembly including a first die and a second die overlying the first die. The first die includes a face side, a back side, and mirror function circuitry. The face side includes a first conductive pad and a second conductive pad horizontally offset from the first conductive pad. The back side opposes the face side. The mirror function circuitry is coupled to the first conductive pad, the second conductive pad, first circuitry, and second circuitry different than the first circuitry. The mirror function circuitry is configured to selectively change electrical connections of the first circuitry and the second circuitry between the first conductive pad and the second conductive pad. The second die includes an additional face side, an additional back side, and additional mirror function circuitry. The additional face side opposes the face side of the first die and includes a first additional conductive pad, and a second additional conductive pad horizontally offset from the first additional conductive pad. The additional back side opposes the additional face side. The additional mirror function circuitry is coupled to the first additional conductive pad, the second additional conductive pad, first additional circuitry, and second additional circuitry different than the first additional circuitry. The additional mirror function circuitry is configured to selectively change electrical connections of the first additional circuitry and the second additional circuitry between the first additional conductive pad and the second additional conductive pad.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. An assembly, comprising:
a first die comprising:
a first pad on a facing surface of the first die;
a second pad on the facing surface of the first die; and
mirror function circuitry configured to swap functionalities of the first pad and the second pad; and
a second die arranged face-to-face with the first die and comprising:
an additional first pad on an additional facing surface of the second die, the additional first pad corresponding to the first pad of the first die, the additional first pad coupled to the second pad of the first die; and
an additional second pad on the additional facing surface of the second die, the additional second pad corresponding to the second pad of the first die, the additional second pad coupled to the first pad of the first die.

2. The assembly of claim 1, wherein the second die further comprises additional mirror function circuitry coupled to the additional first pad and the additional second pad.

3. The assembly of claim 2, wherein:
the first die further comprises a mirror function inverter coupled to the mirror function circuitry and configured to invert a signal output by the mirror function circuitry; and
the second die further comprises an additional mirror function inverter coupled to the additional mirror function circuitry and configured to invert an additional signal output by the additional mirror function circuitry.

4. The assembly of claim 3, wherein:
the first die further comprises an inverter trigger configured to activate the mirror function inverter of the first die; and
the second die further comprises an additional inverter trigger operable to activate the additional mirror function inverter of the second die.

5. The assembly of claim 4, wherein:
the inverter trigger of the first die comprises a bond pad; and
the additional inverter trigger of the second die comprises an additional bond pad.

6. The assembly of claim 5, wherein:
the bond pad of the first die is coupled to an output driver supply (V_{DDQ}) terminal; and
the additional bond pad of the second die is coupled to a ground (V_{SS}) terminal.

7. The assembly of claim 4, wherein:
the inverter trigger of the first die comprises a fuse; and
the additional inverter trigger of the second die comprises an additional fuse.

8. The assembly of claim 7, wherein:
the fuse of the first die is not shorted; and
the additional fuse of the second die is shorted.

9. The assembly of claim 2, wherein the mirror function circuitry of the first die and the additional mirror function circuitry of the second die are each coupled to mirror package circuitry, the mirror package circuitry configured to activate one of the mirror function circuitry and the additional mirror function circuitry relative to the other of the mirror function circuitry and the additional mirror function circuitry.

10. The assembly of claim 1, wherein:
the first pad of the first die and the additional second pad of the second die are coupled to circuitry of an underlying base structure; and
the second pad of the first die and the additional first pad of the second die are coupled to additional circuitry of the underlying base structure.

11. An assembly, comprising:
a die comprising:
a face side;
a back side vertically opposing the face side;
a first bond pad on the face side;
a second bond pad on the face side; and
mirror function circuitry coupled to the first bond pad and the second bond pad, the mirror function circuitry configured to swap which additional circuitries the first bond pad and the second bond pad are respectively coupled to with one another; and
an additional die vertically overlying the die and comprising:
an additional face side relatively more proximate to the face side of the die than the back side of the die;
an additional back side vertically opposing the additional face side;
a first additional bond pad on the additional face side and horizontally overlapping the second bond pad of the die in a first direction;
a second additional bond pad on the additional face side and horizontally overlapping the first bond pad of the die in the first direction; and
additional mirror function circuitry coupled to the first additional bond pad and the second additional bond pad.

12. The assembly of claim 11, further comprising:
conductive routing structures vertically interposed between and coupling the first bond pad of the die and the second additional bond pad of the additional die; and
additional routing structures vertically interposed between and coupling the second bond pad of the die and the first additional bond pad of the additional die.

13. The assembly of claim 12, wherein all of the conductive routing structures are completely horizontally offset, in the first direction, from all of the additional routing structures.

14. The assembly of claim 13, wherein:
the first additional bond pad of the additional die horizontally overlaps, in the first direction, the first bond pad of the die; and
the second additional bond pad of the additional die horizontally overlaps, in the first direction, the second bond pad of the die.

15. The assembly of claim 13, wherein:
the conductive routing structures are coupled to further circuitries within a base structure vertically underlying the die; and
the additional conductive routing structures are coupled to other circuitries within the base structure.

16. The assembly of claim 11, wherein:
the die further comprises:
mirror function inverter circuitry coupled to the mirror function circuitry, the mirror function inverter circuitry configured to invert a signal output by the mirror function inverter; and
inverter trigger circuitry coupled to the mirror function inverter circuitry, the inverter trigger circuitry configured to control activation and deactivation of the mirror function inverter circuitry; and
the additional die further comprises:
additional mirror function inverter circuitry coupled to the additional mirror function circuitry, the additional mirror function inverter circuitry configured to invert an additional signal output by the additional mirror function inverter; and
additional inverter trigger circuitry coupled to the additional mirror function inverter circuitry, the additional inverter trigger circuitry configured to control activation and deactivation of the additional mirror function inverter circuitry.

17. The assembly of claim 16, wherein:
the inverter trigger circuitry comprises a conductive pad coupled to an output driver supply (V_{DDQ}) terminal; and
additional inverter trigger circuitry comprises an additional conductive pad coupled to a ground (V_{SS}) terminal.

18. The assembly of claim 16, wherein:
the inverter trigger circuitry comprises a non-shorted fuse coupled to an output driver supply (V_{DDQ}) terminal; and
the additional inverter trigger circuitry comprises a shorted fuse coupled to a ground (V_{SS}) terminal.

19. An electronic system comprising:
a dual die assembly comprising:
a first die comprising:
a face side comprising:
a first conductive pad; and
a second conductive pad horizontally offset from the first conductive pad;
a back side opposing the face side; and
mirror function circuitry coupled to the first conductive pad, the second conductive pad, first circuitry, and second circuitry different than the first circuitry, the mirror function circuitry configured to selectively change electrical connections of the first circuitry and the second circuitry between the first conductive pad and the second conductive pad;
a second die overlying the first die and comprising:
an additional face side opposing the face side of the first die and comprising:
a first additional conductive pad; and
a second additional conductive pad horizontally offset from the first additional conductive pad;
an additional back side opposing the additional face side; and
additional mirror function circuitry coupled to the first additional conductive pad, the second additional conductive pad, first additional circuitry, and second additional circuitry different than the first additional circuitry, the additional mirror function circuitry configured to selectively change electrical connections of the first additional circuitry and the second additional circuitry between the first additional conductive pad and the second additional conductive pad.

20. The electronic system of claim 19, further comprising:
first conductive routing structures interposed between and coupling the first conductive pad of the first die and the second additional conductive pad of the second die; and
second conductive routing structures interposed between and coupling the first conductive pad of the first die and the first additional conductive pad of the second die, the second conductive routing structures all positioned substantially entirely outside of horizontal areas of the first conductive routing structures.
